(19) United States
(12) Patent Application Publication
(10) Pub. No.: US 2024/0120440 A1
(43) Pub. Date: Apr. 11, 2024

(54) SEMICONDUCTOR STRUCTURE

(71) Applicant: ENKRIS SEMICONDUCTOR, INC., Suzhou (CN)

(72) Inventors: Weihua LIU, Suzhou (CN); Kai CHENG, Suzhou (CN)

(73) Assignee: ENKRIS SEMICONDUCTOR, INC., Suzhou (CN)

(21) Appl. No.: 18/334,569

(22) Filed: Jun. 14, 2023

(30) Foreign Application Priority Data
Oct. 9, 2022 (CN) 202211228459.8

(51) Int. Cl. H01L 33/06; H01L 33/14; H01L 33/32

(52) U.S. Cl. CPC H01L 33/06; H01L 33/145; H01L 33/325

(57) ABSTRACT

Disclosed is a semiconductor structure. The semiconductor structure includes: a multiple quantum well layer including a quantum barrier layer and a quantum well layer which are alternately arranged; and a protective layer formed on the quantum well layer, where the protective layer is made of an oxygen-doped nitride material. In the present disclosure, the presence of the oxygen-doped protective layer may achieve a longer luminous wavelengths through an InGaN quantum well material with a lower In component.

### CROSS-REFERENCE TO RELATED APPLICATIONS

The present application claims priority to Chinese Patent Application No. 202211228459.8, filed on Oct. 9, 2022, which is hereby incorporated by reference in its entirety.

### TECHNICAL FIELD

The present disclosure relates to the field of semiconductor technologies, and in particular, to a semiconductor structure.

### BACKGROUND

GaN materials are used in fields such as lighting and display, and are generally used in a GaN-based Light-Emitting Diode (LED) prepared by a Metal-Organic Chemical Vapor Deposition (MOCVD) method. A light emitting region of the GaN-based LED is mainly a Multiple Quantum Well (MQW) structure composed of GaN and InGaN materials periodically, where a material of a quantum well is InGaN. A growth of the InGaN/GaN MQW with high-quality and high In component is crucial to realizing long-wavelength light emitting devices. Since optimal growth temperatures of InGaN and GaN materials are different, if a GaN quantum barrier layer is grown at a lower temperature, a crystal quality of the quantum barrier layer would be deteriorated and a luminous efficiency would be reduced.

At present, the GaN quantum barrier layer is commonly grown at a higher temperature, but this may cause an InGaN quantum well layer to decompose during a heating process, so that the In component of the quantum well layer may be reduced. On the other hand, with the increase of a demand for In component in InGaN, a temperature of an epitaxial quantum well is much lower than a temperature of an epitaxial quantum barrier, and a temperature difference is greater. Therefore, during a subsequent process of an epitaxial growth of quantum barrier materials, the completed epitaxial quantum well materials are prone to decomposition and outward migration due to the higher temperature of the epitaxial quantum barrier, and even decompose and precipitate materials such as In and Ga in a metal state, resulting in a deterioration in the crystal quality of quantum well materials, a significant decline in quantum efficiency within a corresponding LED and a large half width of a characteristic luminescence spectrum.

### SUMMARY

In view of this, embodiments of the present disclosure provide a semiconductor structure to solve the technical problem that an InGaN quantum well layer with high In component is difficult to implement in a related art.

According to an aspect of the present disclosure, a semiconductor structure is provided, and the semiconductor structure includes:
a multiple quantum well layer including a quantum barrier layer and a quantum well layer which are alternately arranged; and
a protective layer formed on the quantum well layer, where the protective layer is made of an oxygen-doped nitride material.

As an optional embodiment, a doping concentration of oxygen element in the protective layer is less than 1E20/cm³.

As an optional embodiment, the quantum well layer is an InGaN quantum well layer, the quantum barrier layer is a GaN quantum barrier layer, and the protective layer is made of an oxygen-doped AlGaN material, an oxygen-doped GaN material, or an oxygen-doped AlInGaN material.

As an optional embodiment, doping concentrations of oxygen element in a plurality of protective layers are increased, along an epitaxial growth direction of the semiconductor structure, layer by layer uniformly or jumpily.

As an optional embodiment, along an epitaxial growth direction of the semiconductor structure, a doping method of oxygen element in each protective layer is uniform doping, increasing doping, decreasing doping, or delta doping.

As an optional embodiment, the protective layer includes a first oxygen component doping layer, and a second oxygen component doping layer away from the quantum well layer, which are stacked.

As an optional embodiment, a doping concentration of the first oxygen component doping layer is greater than a doping concentration of the second oxygen component doping layer.

As an optional embodiment, the protective layer is made of oxygen/magnesium co-doped material, and a doping concentration of oxygen element in the protective layer and a doping concentration of magnesium element in the protective layer are less than 1E20/cm³.

As an optional embodiment, a trend of the doping concentration of magnesium element in the protective layer is the same as a trend of the doping concentration of oxygen element in the protective layer.

As an optional embodiment, thicknesses of a plurality of protective layers are increased, along the epitaxial growth direction of the semiconductor structure, layer by layer.

As an optional embodiment, along an epitaxial growth direction of the semiconductor structure, a thickness of each protective layer is less than 5 nm.

As an optional embodiment, an electron blocking layer is formed on the multiple quantum well layer, and the electron blocking layer is made of oxygen/magnesium co-doped AlGaN material.

As an optional embodiment, a doping concentration of oxygen element in the electron blocking layer and a doping concentration of magnesium element in the electron blocking layer are less than 1E20/cm³.

As an optional embodiment, a content ratio of oxygen element to magnesium element in the electron blocking layer is greater than 0.5 and less than 2.

As an optional embodiment, a doping method of oxygen element in the electron blocking layer is uniform doping, increasing doping, decreasing doping, or delta doping.

As an optional embodiment, the electron blocking layer is divided, along an epitaxial growth direction of the semiconductor structure, into a plurality of sub regions, and doping concentrations of oxygen element in at least two sub regions of the plurality of sub regions are different; or
the electron blocking layer is divided, along a horizontal direction, into a plurality of sub regions, and doping concentrations of oxygen element in at least two sub regions of the plurality of sub regions are different.

As an optional embodiment, a trend of a doping concentration of magnesium element in the electron blocking layer is the same as a trend of a doping concentration of oxygen element in the electron blocking layer.

### BRIEF DESCRIPTION OF THE DRAWINGS

FIG. 1 is a schematic diagram of a semiconductor structure according to an embodiment of the present disclosure.

FIG. 2 is a schematic diagram of a semiconductor structure according to another embodiment of the present disclosure.

FIG. 3a is a schematic diagram of a semiconductor structure according to another embodiment of the present disclosure.

FIG. 3b is a schematic diagram of a change in doping concentration of oxygen element in a protective layer of a semiconductor structure according to an embodiment of the present disclosure.

FIG. 3c is a schematic diagram of a change in doping concentration of oxygen element in a protective layer of a semiconductor structure according to another embodiment of the present disclosure.

FIG. 4 is a schematic diagram of a semiconductor structure according to another embodiment of the present disclosure.

FIG. 5 is a schematic diagram of a semiconductor structure according to another embodiment of the present disclosure.

FIG. 6a is a schematic diagram of a semiconductor structure according to another embodiment of the present disclosure.

FIG. 6b is a schematic diagram of a semiconductor structure according to another embodiment of the present disclosure.

### DETAILED DESCRIPTION OF THE EMBODIMENTS

The technical solutions in the embodiments of the present disclosure are described clearly and completely below with reference to the drawings of the embodiments of the present disclosure. Apparently, the described embodiments are only a part, but not all embodiments of the present disclosure. All other embodiments that may be obtained by those of ordinary skill in the art based on the embodiments in the present disclosure without any inventive efforts fall into the protection scope of the present disclosure.

The present disclosure provides a semiconductor structure to solve the technical problem that an InGaN quantum well layer with high In component is difficult to implement in a related art. The semiconductor structure includes: an n-type semiconductor layer; a multiple quantum well layer including a quantum barrier layer and a quantum well layer which are alternately arranged; a protective layer formed on the quantum well layer, where the protective layer is made of an oxygen-doped nitride material; and a p-type semiconductor layer. In the present disclosure, after oxygen doping, the nitride protective layer may further improve an energy band width of the protective layer and the material quality of the semiconductor structure, and reduce defect density, so that a better protection for the quantum well may be provided, the precipitation of In in the InGaN quantum well may be avoided, and a longer luminous wavelength may be achieved by using the InGaN quantum well material with a lower In component.

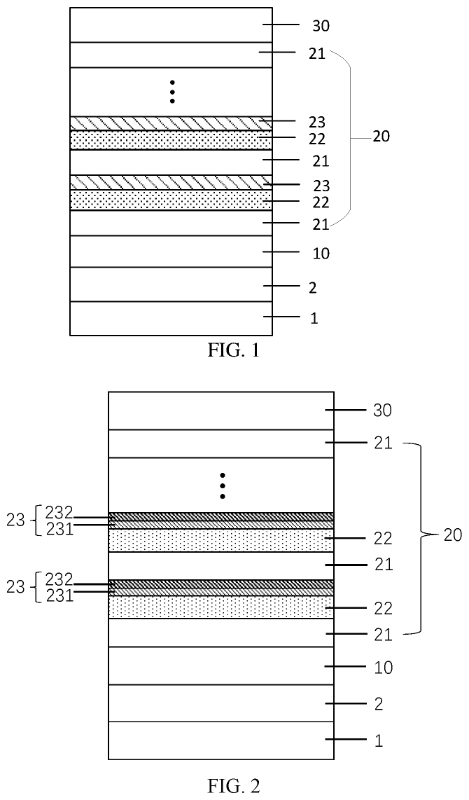

The semiconductor structure mentioned in the present disclosure may be further described below with reference to FIG. 1 to FIG. 6b.

FIG. 1 is a schematic diagram of a semiconductor structure according to an embodiment of the present disclosure.

As shown in FIG. 1, the semiconductor structure includes: an n-type semiconductor layer 10; a multiple quantum well layer 20 formed on the n-type semiconductor layer 10, where the multiple quantum well layer 20 includes a quantum barrier layer 21 and a quantum well layer 22 which are alternately arranged; a protective layer 23 formed on the quantum well layer 22; a p-type semiconductor layer 30 formed on the multiple quantum well layer 20. The protective layer 23 is made of an oxygen-doped nitride material.

In this embodiment, the semiconductor structure further includes a substrate 1. A material of the substrate 1 includes any one or more combinations of Si, Al₂O₃, GaN, SiC, or AlN. To alleviate a stress in an epitaxial structure on the substrate and avoid cracking of the epitaxial structure, the semiconductor structure may further include a buffer layer 2 prepared on the substrate 1, and a material of the buffer layer 2 may include one or more of GaN, AlGaN, AlInGaN, and is not limited to this.

In this embodiment, materials of the n-type semiconductor layer 10 and the p-type semiconductor layer 30 are nitride semiconductors, and the materials of the n-type semiconductor layer 10 and the p-type semiconductor layer 30 may be the same or different. The n-type doped ions in the n-type semiconductor layer 10 may be at least one of Si ions, Ge ions, Sn ions, Se ions, or Te ions. The p-type doped ions in the p-type semiconductor layer 30 may be at least one of Mg ions, Zn ions, Ca ions, Sr ions, or Ba ions. The growth of n-type semiconductor layer 10 and p-type semiconductor layer 30 may be in-situ growth, or they may be prepared by Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal Organic Chemical Vapor Deposition (MOCVD), or a combination thereof.

In this embodiment, a band gap of the quantum barrier layer 21 is greater than a band gap of the quantum well layer 22. For example, a material of the quantum barrier layer 21 is GaN, a material of the quantum well layer 22 is InGaN, and optionally, the protective layer 23 is made of an oxygen-doped AlGaN material, an oxygen-doped GaN material, or an oxygen-doped AlInGaN material.

In this embodiment, the protective layer 23 is doped with oxygen, and along an epitaxial growth direction of the semiconductor structure, a doping method of oxygen element in each protective layer is uniform doping, increasing doping, decreasing doping, or delta doping. A doping concentration of oxygen element is less than 1E20/cm³. A growth method of delta doping is to disconnect three family sources (such as gallium source, aluminum source) while introducing a donor doped oxygen source, so that the donor doped oxygen atoms present a distribution similar to the delta function inside the material. This growth method of modulating the energy band by doping in a limited area of the epitaxial layer may reduce ionization energy. A trend of a doping concentration of magnesium element is the same as a trend of a doping concentration of oxygen element, and the doping concentrations of oxygen element and magnesium element are less than 1E20/cm³. If the doping concentration of magnesium element is too high, the carrier scattering may be enhanced, and the carrier mobility may be significantly reduced.

Specifically, when the protective layer 23 is made of GaN material, oxygen element is introduced and oxygen atoms are used to replace N atoms in the GaN protective layer. Because a crystal cell of Ga—O is greater than a crystal cell of Ga—N, a tensile stress formed by the oxygen element doped protective layer 23 based on the formation of the InGaN quantum well layer 22 may be alleviated and released, so that the oxygen element doped protective layer 23 has a higher material quality and a lower defect density. Thus, a better protection for the quantum well layer 22 may be provided, that is, the precipitation of In in the InGaN quantum well layer 22 may be avoided. Moreover, since the oxygen doped GaN protective layer 23 has a wider band gap compared with GaN, under the effect of an electric field, a heterojunction formed by the oxygen doped GaN protective layer 23 and the InGaN quantum well layer 22, has larger energy band bending at its interface end. That is, the distortion of the InGaN quantum well layer 22 is larger, and the band gap is narrower, so that a longer luminous wavelength may be achieved by using the InGaN quantum well material with a lower In component, and a local area has more electrons, thereby significantly increasing the carrier density in a thin layer, improving the probability of radiative recombination and the luminous efficiency.

FIG. 2 is a schematic diagram of a semiconductor structure according to another embodiment of the present disclosure.

Referring to FIG. 2, a difference between the semiconductor structure in this embodiment and the semiconductor structure in the embodiment of FIG. 1 is that the protective layer 23 includes: a first oxygen component doping layer 231, and a second oxygen component doping layer 232 away from the quantum well layer 22, which are stacked. A doping concentration of the first oxygen component doping layer 231 is greater than a doping concentration of the second oxygen component doping layer 232. The doping concentration of the first oxygen component doping layer 231 is relatively high, so that the quantum well layer 22 may be protected better and the precipitation of In in the InGaN quantum well may be avoided. The doping concentration of the second oxygen component doping layer 232 away from the quantum well layer 22 is reduced, and the difference in lattice constant between the second oxygen component doping layer 232 and the quantum barrier layer 21 on it is reduced, so that the crystal growth quality of the quantum barrier layer 21 on it may be ensured. The first oxygen component doping layer 231 and the second oxygen component doping layer 232 are grown by a stepwise heating method in the protective layer 23, so that In in the quantum well layer 22 may be better protected by the protective layer 23, the precipitation of In during subsequent epitaxial growth of the quantum barrier layer 21 may be reduced, and the growth temperature of the quantum barrier layer 21 may be increased, thereby improving the crystal quality of the multiple quantum well layer 20 and increasing the quantum efficiency within the light-emitting diode effectively.

Besides the above difference, other structures of the semiconductor structure in this embodiment may refer to the corresponding structures of the semiconductor structure in the embodiment of FIG. 1.

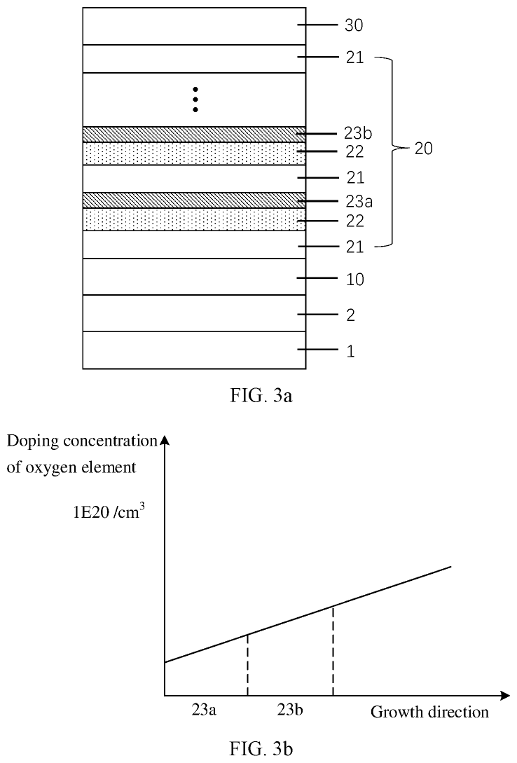

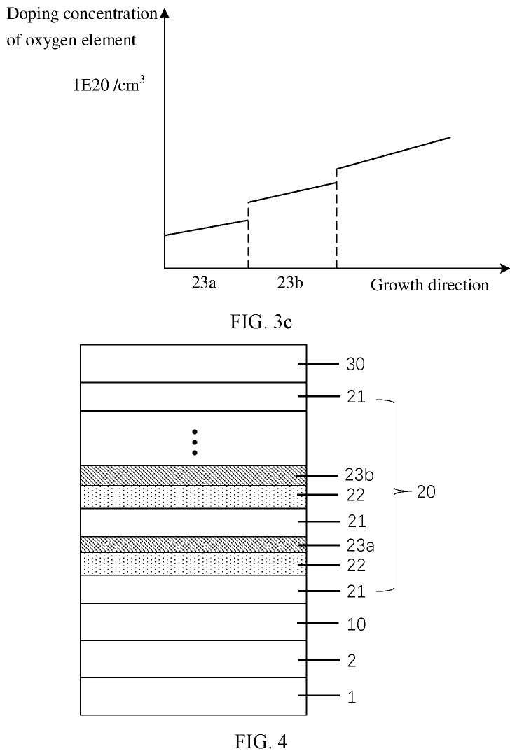

FIG. 3a is a schematic diagram of a semiconductor structure according to another embodiment of the present disclosure.

FIG. 3b is a schematic diagram of a change in doping concentration of oxygen element in a protective layer of a semiconductor structure according to an embodiment of the present disclosure.

FIG. 3c is a schematic diagram of a change in doping concentration of oxygen element in a protective layer of a semiconductor structure according to another embodiment of the present disclosure.

Referring to FIG. 3a, a difference between the semiconductor structure in this embodiment and the semiconductor structures in the embodiments of FIG. 1 and FIG. 2 is that doping concentrations of oxygen element in a plurality of protective layers (23a, 23b, . . . ) are increased, along the epitaxial growth direction of the semiconductor structure, layer by layer uniformly (FIG. 3b) or jumpily (FIG. 3c). The doping concentrations of oxygen element in the plurality of protective layers (23a, 23b, . . . ) are gradually increased to improve the film quality of a subsequent growth protective layer, and the surface morphology of the material may be changed and the optical quality may be improved, thereby improving the luminous efficiency of LED.

Besides the above difference, other structures of the semiconductor structure in this embodiment may refer to the corresponding structures of the semiconductor structures in the embodiments of FIG. 1 and FIG. 2.

FIG. 4 is a schematic diagram of a semiconductor structure according to another embodiment of the present disclosure.

Referring to FIG. 4, a difference between the semiconductor structure in this embodiment and the semiconductor structures in the embodiments of FIG. 1, FIG. 2 and FIG. 3a is that thicknesses of the plurality of protective layers 23a, 23b, . . . are increased, along the epitaxial growth direction of the semiconductor structure, layer by layer. Along the epitaxial growth direction of the semiconductor structure, a thickness of each protective layer 23a, 23b, . . . is less than 5 nm. Optionally, the plurality of protective layers 23a, 23b, . . . are made of an oxygen-doped GaN material, an oxygen-doped AlGaN material, or an oxygen-doped AlInGaN material. Along the epitaxial growth direction of the semiconductor structure, the thicknesses of the plurality of the protective layers 23a, 23b, . . . are also increased layer by layer with the increase of In components in the plurality of quantum well layers, thereby increasing the thickness of the protective layer, so that the occurrence of In atoms escape in the quantum well layers may be better suppressed, and a more effective protection for the InGaN quantum well layers may be provided.

Besides the above difference, other structures of the semiconductor structure in this embodiment may refer to the corresponding structures of the semiconductor structures in the embodiments of FIG. 1, FIG. 2 and FIG. 3a.

Another embodiment of the present disclosure provides a semiconductor structure, and a difference between the semiconductor structure in this embodiment and the semiconductor structures in the embodiments of FIG. 1, FIG. 2, FIG. 3a and FIG. 4 is that the protective layer 23 is made of oxygen/magnesium co-doped material, a doping concentration of oxygen element and a doping concentration of magnesium element are less than 1E20/cm³ respectively, and a trend of the doping concentration of magnesium element is the same as a trend of the doping concentration of oxygen element in the protective layer 23. Specifically, each Ga—O or Al—O bond has one additional electron when the oxygen element is doped in the protective layer 23. By simultaneously doping magnesium element with oxygen, a Mg—O ion bond is formed, so as to prevent the protective layer 23 from being n-type and affecting the normal radiative recombination luminescence of carriers in the multiple quantum well layer 20.

Besides the above difference, other structures of the semiconductor structure in this embodiment may refer to the corresponding structures of the semiconductor structures in the embodiments of FIG. 1, FIG. 2, FIG. 3a and FIG. 4.

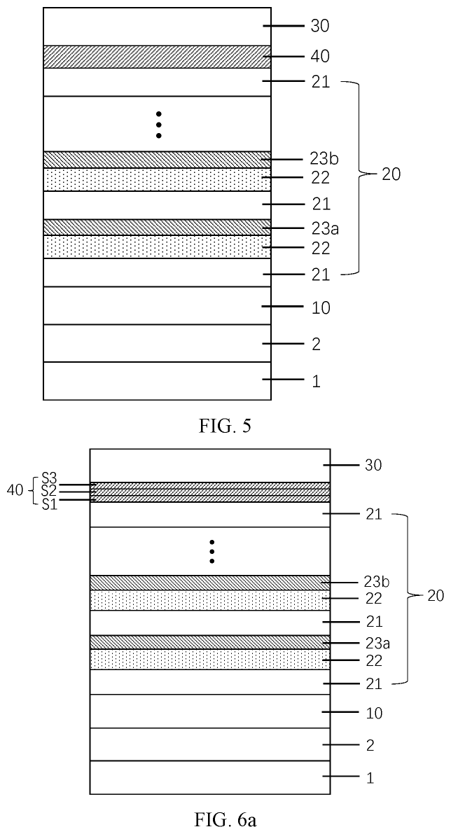

FIG. 5 is a schematic diagram of a semiconductor structure according to another embodiment of the present disclosure.

Referring to FIG. 5, a difference between the semiconductor structure in this embodiment and the semiconductor structures in the above embodiments is that an electron blocking layer 40 is formed on the multiple quantum well layer 20, and the electron blocking layer 40 is made of oxygen/magnesium co-doped AlGaN material. A doping method of oxygen element is uniform doping, increasing doping, decreasing doping, or delta doping, and a trend of a doping concentration of magnesium element is the same as a trend of a doping concentration of oxygen element. The doping concentrations of oxygen element and magnesium element in the electron blocking layer 40 are less than 1E20/cm³ respectively, and a content ratio of oxygen element to magnesium element is greater than 0.5 and less than 2.

The electron blocking layer 40 of the present disclosure is made of oxygen/magnesium co-doped AlGaN material. Since the Al—O bond or Ga—O bond formed by O⁻ and Al⁺/Ga⁺ has a stronger chemical bond energy compared with the Al—N/Ga—N bond, the chemical stability and material quality of the AlGaN electron blocking layer 40 may be improved. On one hand, by doping an activating donor electron-oxygen atom, an acceptor-magnesium atom may be effectively activated, and the formation energy of the co-doped system is lower and more stable. On the other hand, by doping the activating donor electron-oxygen atom, a bond length of the Mg—N bond formed by magnesium atom and N atom in the AlGaN electron blocking layer 40 may be effectively shortened and the bonding strength of the Mg—N bond is greater, so that a solid solubility of magnesium atoms in the AlGaN electron blocking layer 40 may be effectively improved, and the stability of the semiconductor structure may be increased. In addition, a passive O—H bond may be formed much easier through the combination of O⁻ and ionized H⁺ in the ammonia and MO source during the epitaxial growth process, so that the probability of forming Mg—H bond and deep level Mg ion when magnesium element is doped into the material of electron blocking layer 40 is greatly reduced, thereby achieving effective doping of magnesium element and achieving the formation of a p-type electron blocking layer material with high carrier concentration after later annealing.

Besides the above difference, other structures of the semiconductor structure in this embodiment may refer to the corresponding structures of the semiconductor structures in the above embodiments.

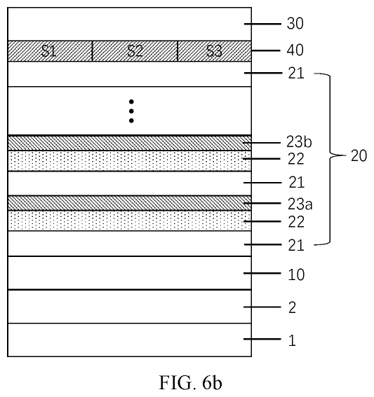

FIG. 6a is a schematic diagram of a semiconductor structure according to another embodiment of the present disclosure.

FIG. 6b is a schematic diagram of a semiconductor structure according to another embodiment of the present disclosure.

Referring to FIG. 6a and FIG. 6b, a difference between the semiconductor structure in this embodiment and the semiconductor structures in the above embodiments is that the electron blocking layer 40 includes a plurality of sub regions.

Specifically, referring to FIG. 6a, the electron blocking layer 40 is divided, along the epitaxial growth direction of the semiconductor structure, into the plurality of sub regions S1, . . . , Sm, and doping concentrations of oxygen element in at least two sub regions of the plurality of sub regions are different; or referring to FIG. 6b, the electron blocking layer is divided, along a horizontal direction (perpendicular to the epitaxial growth direction of the semiconductor structure), into the plurality of sub regions S1, . . . , Sm, and doping concentrations of oxygen element in at least two sub regions of the plurality of sub regions are different. The band gap between the electron blocking layer 40 and the multiple quantum well layer 20 may be increased through the plurality of sub regions S1, . . . , Sm of the electron blocking layer 40, so that the limiting effect on electrons may be enhanced, thereby further reducing the number of electrons entering the P-type semiconductor layer 30, and further improving the luminous efficiency.

Besides the above difference, other structures of the semiconductor structure in this embodiment may refer to the corresponding structures of the semiconductor structures in the above embodiments.

Compared with the related art, the beneficial effects of the present disclosure are:

The protective layer on the InGaN quantum well layer of the multiple quantum well layer in the semiconductor structure of the present disclosure is made of an oxygen-doped nitride material, and oxygen atoms are used to replace N atoms in the GaN protective layer. Because a crystal cell of Ga—O is greater than a crystal cell of Ga—N, a tensile stress formed by the oxygen element doped protective layer based on the formation of the InGaN quantum well layer may be alleviated and released, so that the oxygen element doped protective layer has a higher material quality and a lower defect density. Thus, a better protection for the quantum well layer may be provided, that is, the precipitation of In in the InGaN quantum well layer may be avoided. Moreover, since the oxygen doped GaN protective layer has a wider band gap compared with GaN, under the effect of an electric field, a heterojunction formed by the oxygen doped GaN protective layer and the InGaN quantum well layer, has larger energy band bending at its interface end. That is, the distortion of the InGaN quantum well layer is larger, and the band gap is narrower, so that a longer luminous wavelength may be achieved by using the InGaN quantum well material with a lower In component, and a local area has more electrons, thereby significantly increasing the carrier density in a thin layer, improving the probability of radiative recombination and the luminous efficiency.

The electron blocking layer of the present disclosure is made of oxygen/magnesium co-doped AlGaN material. Since the Al—O bond or Ga—O bond formed by O⁻ and Al⁺/Ga⁺ has a stronger chemical bond energy compared with the Al—N/Ga—N bond, the chemical stability and material quality of the AlGaN electron blocking layer may be improved. On one hand, by doping an activating donor electron-oxygen atom, an acceptor-magnesium atom may be effectively activated, and the formation energy of the co-doped system is lower and more stable. On the other hand, by doping the activating donor electron-oxygen atom, a bond length of the Mg—N bond formed by magnesium atom and N atom in the AlGaN electron blocking layer may be effectively shortened and the bonding strength of the Mg—N bond is greater, so that a solid solubility of magnesium atoms in the AlGaN electron blocking layer may be effectively improved, and the stability of the semiconductor structure may be increased. In addition, a passive O—H bond may be formed much easier through the combination of O⁻ and ionized H⁺ in the ammonia and MO source during the epitaxial growth process, so that the probability of forming Mg—H bond and deep level Mg ion when magnesium element is doped into the material of electron blocking layer is greatly reduced, thereby achieving effective doping of magnesium element and achieving the formation of a p-type electron blocking layer material with high carrier concentration after later annealing.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the described specific features, structures, materials, or characteristics may be combined in an appropriate manner in any one or more embodiments or examples. In addition, those of skill in the art may combine and permutation the different embodiments or examples described in this specification, as well as the features of different embodiments or examples, without contradiction.

The above embodiments are only the preferred embodiments of the present disclosure, and are not intended to limit the protection scope of the present disclosure. Any modification, equivalent replacement, improvement and so on made in the spirit and principle of the present disclosure shall fall into the protection scope of the present disclosure.

What is claimed is:

1. A semiconductor structure, comprising:
a multiple quantum well layer comprising a quantum barrier layer and a quantum well layer which are alternately arranged; and
a protective layer formed on the quantum well layer, wherein the protective layer is made of an oxygen-doped nitride material.

2. The semiconductor structure according to claim 1, wherein a doping concentration of oxygen element in the protective layer is less than 1E20/cm³.

3. The semiconductor structure according to claim 1, wherein doping concentrations of oxygen element in a plurality of protective layers are increased, along an epitaxial growth direction of the semiconductor structure, layer by layer uniformly or jumpily.

4. The semiconductor structure according to claim 1, wherein along an epitaxial growth direction of the semiconductor structure, a doping method of oxygen element in each protective layer is uniform doping, increasing doping, decreasing doping, or delta doping.

5. The semiconductor structure according to claim 1, wherein the protective layer comprises a first oxygen component doping layer, and a second oxygen component doping layer away from the quantum well layer, which are stacked.

6. The semiconductor structure according to claim 5, wherein a doping concentration of the first oxygen component doping layer is greater than a doping concentration of the second oxygen component doping layer.

7. The semiconductor structure according to claim 1, wherein the protective layer is made of oxygen/magnesium co-doped material, and a doping concentration of oxygen element in the protective layer and a doping concentration of magnesium element in the protective layer are less than 1E20/cm³.

8. The semiconductor structure according to claim 7, wherein a trend of the doping concentration of magnesium element in the protective layer is the same as a trend of the doping concentration of oxygen element in the protective layer.

9. The semiconductor structure according to claim 1, wherein the quantum well layer is an InGaN quantum well layer, the quantum barrier layer is a GaN quantum barrier layer, and the protective layer is made of an oxygen-doped AlGaN material, an oxygen-doped GaN material, or an oxygen-doped AlInGaN material.

10. The semiconductor structure according to claim 9, wherein In components of a plurality of quantum well layers are increased, along an epitaxial growth direction of the semiconductor structure, layer by layer.

11. The semiconductor structure according to claim 10, wherein thicknesses of a plurality of protective layers are increased, along the epitaxial growth direction of the semiconductor structure, layer by layer.

12. The semiconductor structure according to claim 1, wherein along an epitaxial growth direction of the semiconductor structure, a thickness of each protective layer is less than 5 nm.

13. The semiconductor structure according to claim 1, wherein an electron blocking layer is formed on the multiple quantum well layer, and the electron blocking layer is made of oxygen/magnesium co-doped AlGaN material.

14. The semiconductor structure according to claim 13, wherein a doping concentration of oxygen element in the electron blocking layer and a doping concentration of magnesium element in the electron blocking layer are less than 1E20/cm³.

15. The semiconductor structure according to claim 13, wherein a content ratio of oxygen element to magnesium element in the electron blocking layer is greater than 0.5 and less than 2.

16. The semiconductor structure according to claim 13, wherein a doping method of oxygen element in the electron blocking layer is uniform doping, increasing doping, decreasing doping, or delta doping.

17. The semiconductor structure according to claim 13, wherein the electron blocking layer is divided, along an epitaxial growth direction of the semiconductor structure, into a plurality of sub regions, and doping concentrations of oxygen element in at least two sub regions of the plurality of sub regions are different.

18. The semiconductor structure according to claim 13, wherein the electron blocking layer is divided, along a horizontal direction perpendicular to an epitaxial growth direction of the semiconductor structure, into a plurality of sub regions, and doping concentrations of oxygen element in at least two sub regions of the plurality of sub regions are different.

19. The semiconductor structure according to claim 13, wherein a trend of a doping concentration of magnesium element in the electron blocking layer is the same as a trend of a doping concentration of oxygen element in the electron blocking layer.

20. The semiconductor structure according to claim 1, further comprising:
an n-type semiconductor layer, wherein the multiple quantum well layer is formed on the n-type semiconductor layer; and
a p-type semiconductor layer formed on the multiple quantum well layer.
